(19) United States
(12) Patent Application Publication
(10) Pub. No.: US 2023/0402815 A1
(43) Pub. Date: Dec. 14, 2023

(54) DEFECT-TOLERANT, SELF-HEALING VCSEL ARRAY ARCHITECTURES WITH VCSEL DEVICES HAVING INTEGRATED FUSE STRUCTURES

(71) Applicant: Sense Photonics, Inc., Durham, NC (US)

(72) Inventors: Scott BURROUGHS, Raleigh, NC (US); James CARTER, Chapel Hill, NC (US); Caesar GARCIA, Durham, NC (US); Kristopher MCGUIRE, Raleigh, NC (US)

(21) Appl. No.: 18/249,866

(22) PCT Filed: Oct. 25, 2021
(86) PCT No.: PCT/US2021/056448

§ 371 Date: Apr. 20, 2023

Related U.S. Application Data
(60) Provisional application No. 63/105,658, filed on Oct. 26, 2020.

(51) Int. Cl. H01S 5/00; H01S 5/183; H01S 5/42

(52) U.S. Cl. CPC H01S 5/0014; H01S 5/183; H01S 5/423

(57) ABSTRACT

A light emitting device includes a semiconductor structure comprising an n-type layer, an active region, and a p-type layer, first and second electrical contacts on the n-type layer and the p-type layer, respectively, and an integrated fuse structure in or on the semiconductor structure. The integrated fuse structure is electrically coupled in series between the first and second electrical contacts, and is actuatable to provide an electrically open state between the first and second electrical contacts responsive to a control signal. Related emitter arrays, methods of fabrication, and methods of operation are also discussed.

### CLAIM OF PRIORITY

This application claims priority from U.S. Provisional Patent Application Ser. No. 63/105,658, filed Oct. 26, 2020, the disclosure of which is incorporated by reference herein in its entirety.

### FIELD

The present disclosure relates to semiconductor-based light emitting devices and related devices and methods of operation.

### BACKGROUND

Many emerging technologies, such as Internet-of-Things (IoT) and autonomous navigation, may involve detection and measurement of distance to objects in three-dimensional (3D) space. For example, automobiles that are capable of autonomous driving may require 3D detection and recognition for basic operation, as well as to meet safety requirements. 3D detection and recognition may also be needed for indoor navigation, for example, by industrial or household robots or toys.

Light based 3D measurements may be superior to radar (low angular accuracy, bulky) or ultra-sound (very low accuracy) in some instances. For example, a light-based 3D sensor system may include a light detector (such as a photodiode or camera) and light source (including one or more semiconductor light emitting elements, such as light emitting diodes (LED) or laser diodes; generally referred to herein as emitters), which typically emits light outside of the visible wavelength range. A vertical cavity surface emitting laser (VCSEL) is one type of emitter that may be used in light-based sensors for measurement of distance and velocity in 3D space. Arrays of emitters may allow for power scaling and can provide very short pulses at higher power density.

Emitter arrays, such as arrays of surface- or edge-emitting laser diodes, may be fabricated using Micro-Transfer Printing (MTP) technology. Such arrays may have electrical interconnect schemes that can present challenges, particularly with respect to failures of discrete emitter devices within the array. For example, due to the small physical size of the emitter devices being processed, and in some instances the nature of the MTP process, electrical screening of emitters may be impractical or impossible in a manufacturing environment. Therefore, a population of emitters fabricated into a single array will typically include some defective emitters.

### SUMMARY

Some embodiments described herein provide methods, systems, and devices including electronic circuits that provide a light source having one or more semiconductor light emitter elements (including one or more LEDs or lasers, such as surface- or edge-emitting laser diodes, including vertical cavity surface emitting lasers; generally referred to herein as emitters).

According to some embodiments, a light emitting device includes a semiconductor structure comprising an n-type layer, an active region, and a p-type layer; first and second electrical contacts on the n-type layer and the p-type layer, respectively; and an integrated fuse structure in or on the semiconductor structure and electrically coupled to the first and/or second electrical contacts. The integrated fuse structure is actuatable to provide an electrically open state responsive to a control signal.

In some embodiments, the integrated fuse structure is electrically coupled in series between the first and second electrical contacts and is actuatable to provide the electrically open state between the first and second electrical contacts responsive to application of the control signal to the first and/or second electrical contacts.

In some embodiments, the control signal comprises a fusing voltage that is greater than an operating voltage of the light emitting device.

In some embodiments, the fusing voltage is about 2.5 to about 4 times the operating voltage.

In some embodiments, the integrated fuse structure has a greater resistance than one or more elements that are electrically coupled in series between the first and second electrical contacts.

In some embodiments, the semiconductor structure further comprises a conduction layer that laterally extends beyond the active region and includes one of the first and second electrical contacts thereon, and the one or more elements comprises a portion of the conduction layer.

In some embodiments, the integrated fuse structure comprises one or more dimensions that are less than that of the portion of the conduction layer.

In some embodiments, the one or more dimensions is between about 0.5 μm (micrometer) to about 3 μm in thickness, about hum to about 300 μm in width, and/or about 1 μm to about 50 μm length.

In some embodiments, the portion of the conduction layer is a first portion, and the integrated fuse structure comprises a second portion of the conduction layer that is integral to the first portion.

In some embodiments, the light emitting device is a laser diode.

In some embodiments, the laser diode is a vertical cavity surface emitting laser (VCSEL).

According to some embodiments, an emitter array comprises a plurality of light emitting devices electrically connected in series and/or parallel on a substrate. The light emitting devices respectively comprise a semiconductor structure comprising an n-type layer, an active region, and a p-type layer; first and second electrical contacts on the n-type layer and the p-type layer, respectively; and an integrated fuse structure in or on the semiconductor structure and electrically coupled to the first and/or second electrical contacts. The integrated fuse structure is actuatable to provide an electrically open state responsive to a control signal.

In some embodiments, the integrated fuse structure is electrically coupled in series between the first and second electrical contacts and is actuatable to provide the electrically open state between the first and second electrical contacts responsive to application of the control signal to the first and/or second electrical contacts.

In some embodiments, the control signal comprises a fusing voltage that is greater than an operating voltage of the light emitting devices.

In some embodiments, the light emitting devices are individually addressable for selective application of the control signal to one or more of the light emitting devices.

In some embodiments, the integrated fuse structure has a greater resistance than one or more elements that are electrically coupled in series between the first and second electrical contacts.

In some embodiments, the semiconductor structure further comprises a conduction layer that laterally extends beyond the active region and includes one of the first and second electrical contacts thereon, and the one or more elements comprises a portion of the conduction layer.

In some embodiments, the light emitting devices are laser diodes that are electrically connected in series and/or parallel by thin film interconnects on the substrate, and the substrate is non-native to the laser diodes.

In some embodiments, the laser diodes are vertical cavity surface emitting lasers (VCSELs).

According to some embodiments, a method of fabricating a light emitting device comprises forming a semiconductor structure comprising an n-type layer, an active region, and a p-type layer; forming first and second electrical contacts on the n-type layer and the p-type layer, respectively; and providing an integrated fuse structure in or on the semiconductor structure and electrically coupled to the first and/or second electrical contacts. The integrated fuse structure is actuatable to provide an electrically open state responsive to a control signal.

In some embodiments, the integrated fuse structure is electrically coupled in series between the first and second electrical contacts and is actuatable to provide the electrically open state between the first and second electrical contacts responsive to application of the control signal to the first and/or second electrical contacts.

In some embodiments, the integrated fuse structure has a greater resistance than one or more elements that are electrically coupled in series between the first and second electrical contacts.

In some embodiments, forming the semiconductor structure comprises forming a conduction layer that laterally extends beyond the active region, forming the first and second electrical contacts comprises forming one of the first and second electrical contacts on the conduction layer, and the one or more elements comprises a portion of the conduction layer.

In some embodiments, providing the integrated fuse structure comprises forming the integrated fuse structure with at least one dimension that is less than that of the portion of the conduction layer.

In some embodiments, the portion of the conduction layer is a first portion, and the integrated fuse structure comprises a second portion of the conduction layer that is integral to the first portion.

According to some embodiments, a method of operating an emitter array comprising a plurality of light emitting devices electrically connected in series and/or parallel comprises performing, by one or more control circuits, operations comprising detecting a failure of at least one of the light emitting devices, where the at least one of the light emitting devices comprises an integrated fuse structure in or on a semiconductor structure thereof and electrically coupled to first and/or second electrical contacts thereof; and applying a control signal to the at least one of the light emitting devices, where the integrated fuse structure is actuatable to provide an electrically open state responsive to the control signal.

In some embodiments, the integrated fuse structure is electrically coupled in series between the first and second electrical contacts and is actuatable to provide the electrically open state between the first and second electrical contacts responsive to application of the control signal to the first and/or second electrical contacts.

In some embodiments, the control signal comprises a fusing voltage that is greater than an operating voltage of the light emitting devices.

In some embodiments, the fusing voltage is about 2.5 to about 4 times the operating voltage.

In some embodiments, the operations further comprise identifying the failure of the at least one of the light emitting devices as an electrical short between the first and second electrical contacts thereof, and applying the control signal comprises selectively applying the control signal to the first and/or second electrical contacts of the at least one of the light emitting devices responsive to the identifying.

In some embodiments, the integrated fuse structure has a greater resistance than one or more elements that are electrically coupled in series between the first and second electrical contacts.

In some embodiments, the light emitting devices are laser diodes that are electrically connected in series and/or parallel by thin film interconnects on a substrate that is non-native to the laser diodes, and are individually addressable by the one or more control circuits for selective application of the control signal thereto.

In some embodiments, the emitter array is a light source of a Light Detection and Ranging (LIDAR) system.

In some embodiments, in any of the light emitting devices, emitter arrays, or methods described above, the light emitting device can be configured to be coupled to a vehicle and oriented relative to an intended direction of travel of the vehicle.

Other devices, apparatus, and/or methods according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF THE DRAWINGS

FIG. 1 is a schematic block diagram illustrating an emitter array and other components of a time of flight (ToF) measurement system or circuit in a lidar application according to some embodiments of the present disclosure.

FIGS. 2, 3A, and 3B are plan views of emitter arrays illustrating example electrical interconnection schemes according to some embodiments of the present disclosure.

FIG. 4A is a cross-sectional view illustrating an emitter device including an example integrated fuse structure according to some embodiments of the present disclosure.

FIG. 4B is a cross-sectional view illustrating the integrated fuse structure of the emitter device of FIG. 4A in an electrically-open state.

FIG. 5A is a plan view illustrating an emitter device including an example integrated fuse structure according to some embodiments of the present disclosure.

FIG. 5B is a plan view illustrating the integrated fuse structure of the emitter device of FIG. 5A in an electrically-open state.

FIGS. 6, 7, and 8 are cross-sectional views illustrating emitter devices including example integrated fuse structures according to some embodiments of the present disclosure.

FIGS. 9A and 9B are flowcharts illustrating methods of operating an emitter array to reduce and/or eliminate effects of defective emitters according to some embodiments of the present disclosure.

### DETAILED DESCRIPTION OF EMBODIMENTS

In the following detailed description, numerous specific details are set forth to provide a thorough understanding of embodiments of the present disclosure. However, it will be understood by those skilled in the art that the present disclosure may be practiced without these specific details. In some instances, well-known methods, procedures, components and circuits have not been described in detail so as not to obscure the present disclosure. It is intended that all embodiments disclosed herein can be implemented separately or combined in any way and/or combination. Aspects described with respect to one embodiment may be incorporated in different embodiments although not specifically described relative thereto. That is, all embodiments and/or features of any embodiments can be combined in any way and/or combination.

Embodiments of the present disclosure provide optical emitter arrays (such as arrays of LEDs, laser diodes, or other semiconductor light emitting devices formed or placed on a common substrate), methods of fabrication, and methods of operating emitters and emitter arrays to provide self-healing functionality. In some embodiments, the self-healing may be implemented by integrating actuatable fuse structures in one or more emitters in the emitter array, which may reduce or prevent problems associated with defective emitters in the emitter array at any point in the lifetime of the emitter array (e.g., during manufacture, after manufacture, and/or during operation). Embodiments of the present disclosure can be applied in lidar systems, illumination systems (such as vehicle headlights) and/or other illumination imagers that may use arrays of discrete emitters, such as LEDs or VCSELs.

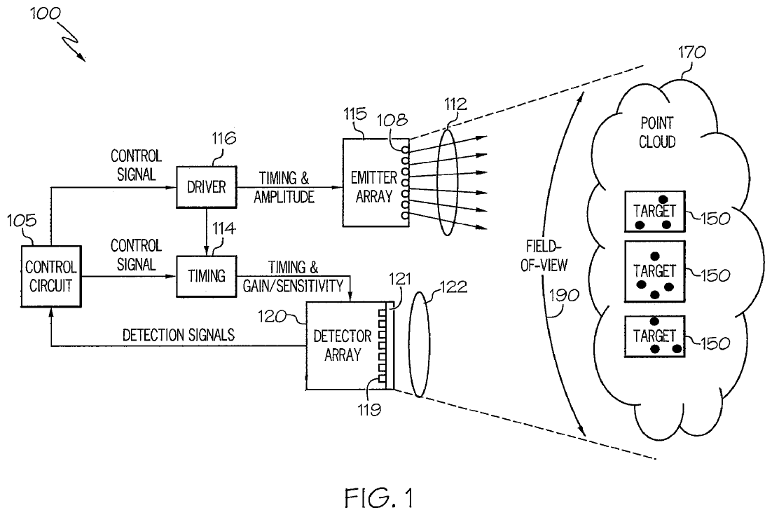

An example application of embodiments of the present disclosure in a lidar system or circuit 100 is shown in FIG. 1. The lidar system 100 includes a control circuit 105, a timing circuit 114, lidar emitter implemented as an emitter array 115 including a plurality of semiconductor light emitting devices (also referred to herein as emitters) 108, and a lidar detector implemented as a detector array 120 including a plurality of detectors 119. The detectors 119 include time-of-flight sensors (for example, an array of single-photon detectors, such as SPADs). One or more of the emitter elements 108 of the emitter array 115 may define emitter units that respectively emit a radiation pulse or continuous wave signal at a time and frequency controlled by a timing generator or driver circuit 116. In particular embodiments, the emitters 108 may be pulsed light sources, such as LEDs or lasers (such as vertical cavity surface emitting lasers (VCSELs)), that are configured to emit light with the operational wavelength range of the lidar system 100. Radiation is reflected back from a target 150, and is sensed by detector pixels defined by one or more detector elements 119 of the detector array 120. The control circuit 105 implements a pixel processor that measures and/or calculates the time of flight of the illumination pulse over the journey from emitter array 115 to target 150 and back to the detectors 119 of the detector array 120, using direct or indirect ToF measurement techniques.

The emitter module or circuit 115 may include an array of semiconductor light emitter elements 108 (e.g., VCSELs), a corresponding array of optical elements 112 coupled to one or more of the emitter elements (e.g., lens(es) 112, such as microlenses), and/or driver electronics 116. The optical elements 112 may be configured to provide a sufficiently low beam divergence of the light output from the emitter elements 108 so as to ensure that respective fields of illumination of either individual or groups of emitter elements 108 do not significantly overlap, and yet provide a beam divergence of the light output from the emitter elements 108 to provide eye safety to observers. In some embodiments, the emitters 108 may be provided on a non-planar (e.g., curved) or flexible substrate so as to contribute to the desired illumination pattern.

The driver electronics 116 may each correspond to one or more emitter elements, and may each be operated responsive to timing control signals with reference to a master clock and/or power control signals that control the peak power of the light output by the emitter elements 108. In some embodiments, each of the emitter elements 108 in the emitter array 115 is connected to and controlled by a respective driver circuit 116. In other embodiments, respective groups of emitter elements 108 in the emitter array 115 (e.g., emitter elements 108 in spatial proximity to each other), may be connected to a same driver circuit 116. The driver circuit or circuitry 116 may include one or more driver transistors configured to control the modulation frequency, timing and amplitude of the optical signal emission that is output from the emitters 108. The maximum optical power output of the emitters 108 may be selected to generate a signal-to-noise ratio of the echo signal from the farthest, least reflective target at the brightest background illumination conditions that can be detected in accordance with embodiments described herein.

Light emission output from one or more of the emitters 108 impinges on and is reflected by one or more targets 150, and the reflected light is detected as an optical signal (also referred to herein as a return signal, echo signal, or echo) by one or more of the detectors 119 (e.g., via receiver optics 122 and/or wavelength-selective filter(s) 121), converted into an electrical signal representation (referred to herein as a detection signal), and processed (e.g., based on time of flight) to define a 3-D point cloud representation 170 of a field of view 190.

Operations of lidar systems in accordance with embodiments of the present disclosure as described herein may be performed by one or more processors or controllers, such as the control circuit 105 of FIG. 1. For example, the control circuit 105 may implement a pixel processor that measures the ToF of the laser pulse and its reflected signal over the journey from emitter array 115 to object 150 and back to the detector array 110. The processor circuit 105′ may also include a sequencer circuit that is configured to coordinate operation of the emitters 108 and detectors 119.

Emitter arrays in accordance with embodiments of the present disclosure may be used in both electrically-scanning (which generate image frames by raster scanning; also referred to herein as e-scanning) and flash or staring lidar systems (where the pulsed light emitting device array 115 emits light for short durations over a relatively large area to acquire images). The description above is primarily with reference to direct ToF (dToF) lidar systems, but it will be understood that embodiments described herein can be applied to indirect ToF (iToF) lidar systems as well.

Still referring to FIG. 1, the emitters 108 may be electrically connected laser diodes, such as VCSELs, and may be operated with strong single pulses at low duty cycle or with pulse trains, typically at wavelengths outside of the visible spectrum (e.g., greater than about 900 nanometers (nm), for example, about 905 nm for GaAs VCSELs or about 1500 nm for InP VCSELs). The emitters 108 may be electrically connected in series and/or parallel by conductive thin-film interconnects on a non-native substrate, i.e., a substrate that is different from a source wafer or substrate on which the emitters were formed. The distribution or population density of the emitters 108 in the emitter array 115 can be selected to define a sparse array (e.g., with a large or varying pitch between adjacent emitters in plan view). The operation of the emitters 108 can be dynamically adjusted or otherwise controlled to reduce optical power density, providing both long range and eye safety at a desired wavelength of operation. Because of sensitivity to background light and the decrease of the signal with distance, several watts of laser power may be required to detect a target 150 at a distance d of up to about 100 meters or more.

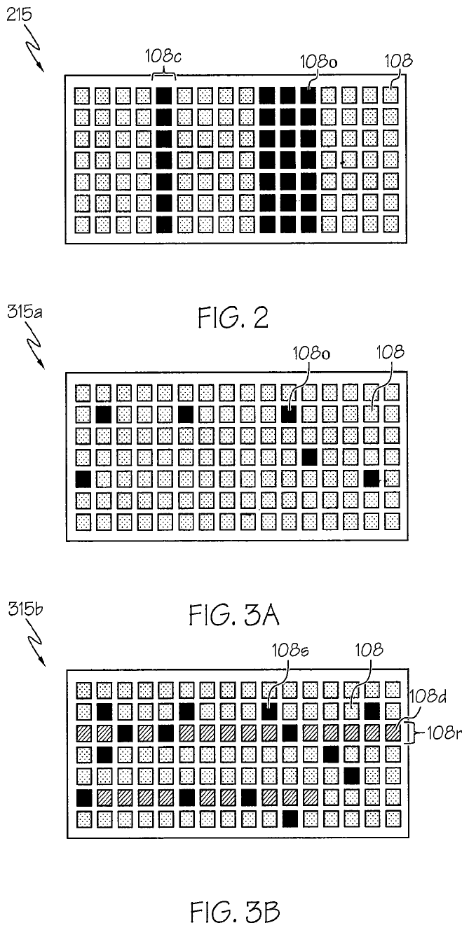

In many interconnect schemes for emitter arrays, such as printed VCSEL arrays, there may be a sensitivity to emitters that fail as “electrical opens” (where the failure of a discrete emitter device defines an open-circuit condition between its anode and cathode; also referred to as an electrically-open state). Such failing emitters can prevent or block current flow to other emitters interconnected in the same “string” of emitters, which are electrically connected in series. As such, the impact of these failing emitters can be multiplied by the number of emitters connected in series. FIG. 2 illustrates an example emitter array 215 including serially-connected emitter strings, whereby the failure of one or more of the emitters 108o in an electrically-open state can result in inoperability of entire strings of emitters 108c. The serially-connected strings 108c of emitters 108 are implemented as columns of the array 215 in FIG. 2, but may be similarly implemented as rows of the array 215 in some embodiments.

A different interconnect scheme, in which the devices of the emitter array are electrically interconnected within a “grid” or “mesh” (which may include serial and parallel electrical connections), may be less sensitive to “electrical opens”. For example, the emitters may be electrically connected in series (e.g., anode-to-cathode) and/or in parallel by conductive thin-film interconnects in or on a surface of a substrate.

FIG. 3A is a plan view of an example emitter array 315a including emitters 108 that are electrically connected in such a grid interconnection scheme. As shown in FIG. 3A, defective emitters 108o that fail as “electrical opens” in a grid interconnection scheme may not prevent current flow to adjacent emitters 108, such that the failure of one emitter 108o may not substantially affect performance of the array 315a.

However, emitter arrays including grid interconnection schemes may be susceptible to greater impact from defective emitters 108s that fail as “electrical shorts” (where the failure of a discrete emitter device defines a short-circuit condition between its anode and cathode; also referred to as an electrically-shorted state). Such failing emitters 108s may draw current from other emitters 108 which are positioned within the grid at the same potential node.

FIG. 3B is a plan view of an example emitter array 315b illustrating susceptibility of adjacent emitters 108 that are electrically connected in a grid interconnection scheme to electrical shorts in one or more adjacent emitters 108s. As shown in FIG. 3B, defective emitters 108s that fail in an electrically-shorted state may result in reduced or interrupted current flow to other emitters 108d, which can result in undesired local dimming (shown in FIG. 3B as local dimming of rows 108r of emitters 108d).

Some embodiments of the present invention provide emitter structures, fabrication methods, and control schemes that can reduce or eliminate problems associated with respective emitter devices in an emitter array that fail as electrical shorts. As noted above, such effects may be particularly problematic in grid interconnect schemes, but embodiments of the present disclosure are not limited thereto. In particular, some embodiments of the present disclosure may provide emitter structures, fabrication methods, and control schemes that can electrically fuse one or more failing or failed emitter devices (e.g., individually or in groups of emitters), that is, to transform the electrically shorted condition or state into an electrically open condition or state.

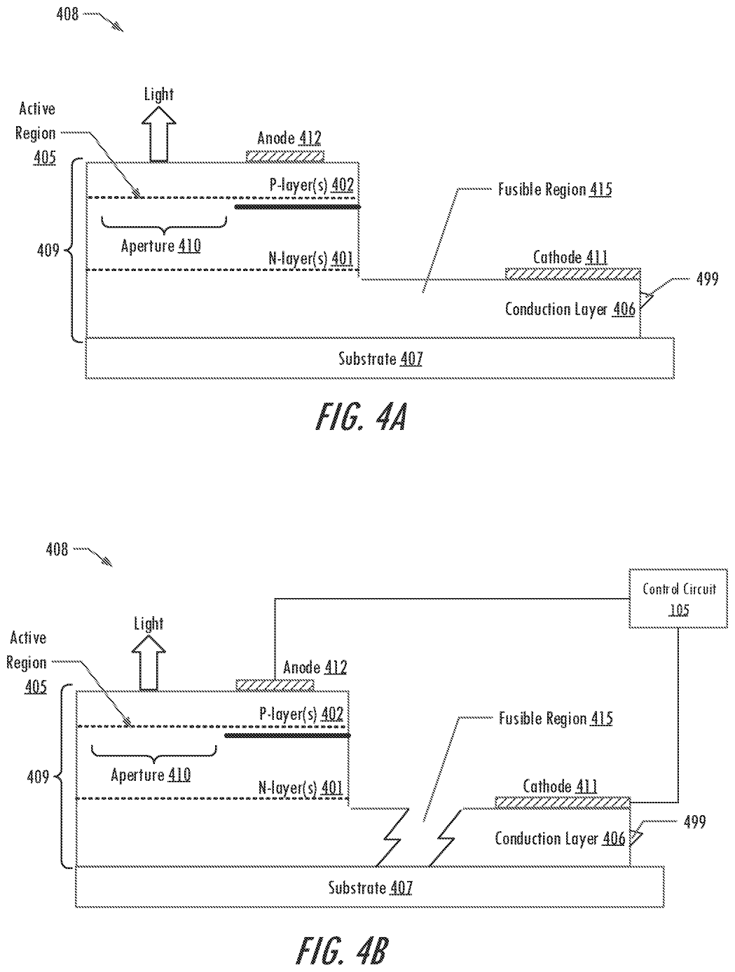

FIG. 4A is a cross-sectional view of an individual semiconductor light emitting device (or “emitter”) 408 including an integrated fusible or fuse structure 415 according to some embodiments of the present disclosure. FIG. 4B is a cross-sectional view illustrating the integrated fuse structure 415 in an electrically-open state responsive to operations described herein.

As shown in FIGS. 4A and 4B, the emitter 408 includes a semiconductor structure 409 including one or more n-type layers (shown as N-layer(s) 401), an active region 405, and one or more p-type layers 402 (shown as P-layer(s) 402). In the examples described herein, the semiconductor structure 409 is illustrated (and may also be referred to) as a mesa structure 409 of a laser diode, including an optical aperture 410 (e.g., defined by an aperture oxidation layer or region) from which light is emitted. In some embodiments, the emitter 408 may be a VCSEL, and the n-type layers 401 and p-type layers 402 may include multiple layers of alternating materials with varying refractive indices, such as n- and p-type distributed Bragg reflectors (DBRs), that define an optical cavity therebetween. A first electrical contact 411 (shown as a cathode) is provided on one or more of the n-type layers 401, and a second electrical contact 412 (shown as an anode contact) is provided on one or more of the p-type layers 402. Although described and illustrated herein with reference to regions of specific conductivity types (i.e., n-type and p-type) by way of example, it will be understood that the conductivity types of the regions in any of the illustrated examples may be reversed (i.e., p-type and n-type) in some embodiments.

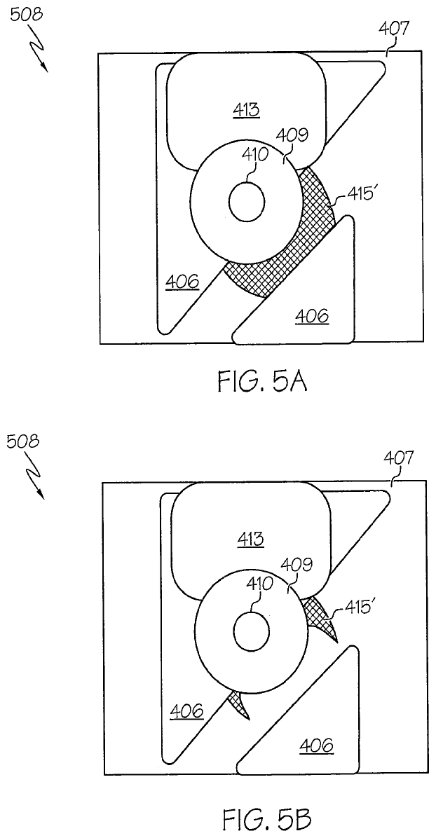

In some embodiments, the emitters 408 may be formed in an array on a substrate 407. The substrate 407 may be non-native substrate, i.e., a substrate that is different from a source wafer or growth substrate on which the emitter 408 was formed. The emitter 408 may be transferred to the substrate 407 using MTP techniques, and thus, may include a broken tether or anchor portion 499 in some embodiments. The emitter 408 may be electrically connected to other emitters 408 by thin film conductive patterns (shown as thin film interconnects 413 in FIGS. 5A and 5B) in a serial or parallel fashion.

Still referring to FIGS. 4A and 4B, an integrated fuse structure 415 is a conductive element that is electrically coupled in series between the anode contact 411 and the cathode contact 412, in or on the semiconductor structure 409. In the example of FIGS. 4A and 4B, the integrated fuse structure 415 is illustrated as a portion of a lateral conduction layer (LCL) 406 that laterally extends from (or under) the mesa structure 409 to the cathode contact 411. More generally, the integrated fuse structure 415 may be a layer or region that is configured to be activated (or “cut”) responsive to a control signal, (e.g., a high voltage pulse), provided for example by a controller or other circuit (e.g., control circuit 105) coupled to the array, in order to provide an electrically open state between the first and second electrical contacts 411 and 412.

In particular, as shown in FIG. 4B, the integrated fuse structure 415 is configured to provide the electrically open state responsive to a control signal applied to the first and/or second electrical contacts 411 and/or 412 by the control circuit 105. That is, the control circuit 105 may be configured to apply the control signal to the cathode and/or anode contacts 411 and/or 412 of one or more emitters 408, and the integrated fuse structure 415 is configured be fused (e.g., transitioned to a non-conductive state) to provide an electrically open state between the first and second electrical contacts 411 and 412 responsive to the control signal. The control signal may have a voltage (also referred to herein as a fusing voltage) that is significantly greater than an operating voltage of the emitter 408, e.g., a voltage of about 3 times or more than the normal operating voltage across the emitter 408. For example, the fusing voltage may be from about 2.5 times to about 4 times the normal operating voltage. More generally, the fusing voltage should be sufficiently greater than typical voltage fluctuations or spikes that may be encountered by the emitter 408 during normal operation, to avoid unintended actuation of the fuse structure 415.

The control circuit 105 may be configured to selectively apply the control signal with the fusing voltage on a per-emitter or per-group of emitters basis, to selectively force one or more electrically shorted devices 408 into a failing state of an electrical open, thereby preventing malfunction of one or more emitters 408 from substantially affecting overall operation of the emitter array. For example, the control circuit 105 may be configured to apply the fusing voltage in a forward bias direction to a specific emitter 408 or group of emitters 408, e.g., during manufacture (using probe tips contacting the array interconnect metal 413 on the anode 411 and/or cathode 412 sides of the emitter 408) and/or during operation (for instance, by identifying and selectively addressing the specific emitter(s) 408).

As shown in FIGS. 4A and 4B, the semiconductor structure 409 includes a lateral conduction layer (LCL) 406 having the first electrical contact 411 (or second electrical contact 412) on an upper surface thereof, facing away from the substrate 407. In some embodiments, the LCL 406 includes conductive material that laterally extends under the layers 401, 402 and the active region 405 of the mesa structure 409, under the cathode contact pad 411, and between those two features. For example, the LCL 409 may be an epitaxial layer or material that is grown concurrently with the epitaxial material of the emitter 408 (e.g., concurrently with one or more layers 401, 402 of the semiconductor structure 409). In another example, the LCL 406 may be any conductive material that is fabricated between the anode contact 412 and the cathode contact 411 of the emitter 408 and acts as a current path, while being or extending outside of the active region 405 of the emitter 408.

In the example of FIGS. 4A and 4B, the integrated fuse structure 415 may be implemented as a portion of the LCL 406. For example, the emitter 408 may be fabricated such that the a portion 415 of the LCL 406 between the layers 401, 402 of the mesa structure 409 and the cathode contact pad 411 has a greater resistance (or the highest resistance) of multiple elements or structures that are in series (e.g., in a serial current path between the anode contact 412 and cathode contact 411) within the device 408, so as to fail in response to an applied control signal having a predetermined voltage, e.g., in excess of about 3 times the normal operating voltage of the emitter 408.

In some embodiments, the integrated fuse structure may be a sublayer of the same or different material than the LCL 406 or other layer of the semiconductor structure 409. FIG. 5A is a plan view illustrating an emitter device 508 (illustrated by way of example as a VCSEL) including an example integrated fuse structure 415′ according to some embodiments of the present disclosure. FIG. 5B is a plan view illustrating the integrated fuse structure 415′ in an electrically-open state. That is, FIG. 5A illustrates the emitter 508 as fabricated, while FIG. 5B illustrates the emitter 508 after application of a control signal (e.g., a high voltage pulse). As shown in FIGS. 5A and 5B, the integrated fuse structure 415′ is a sublayer that is configured to be actuated or cut responsive to a control signal of a sufficient voltage, so as to create the electrically-open state between the contacts 411 and 412.

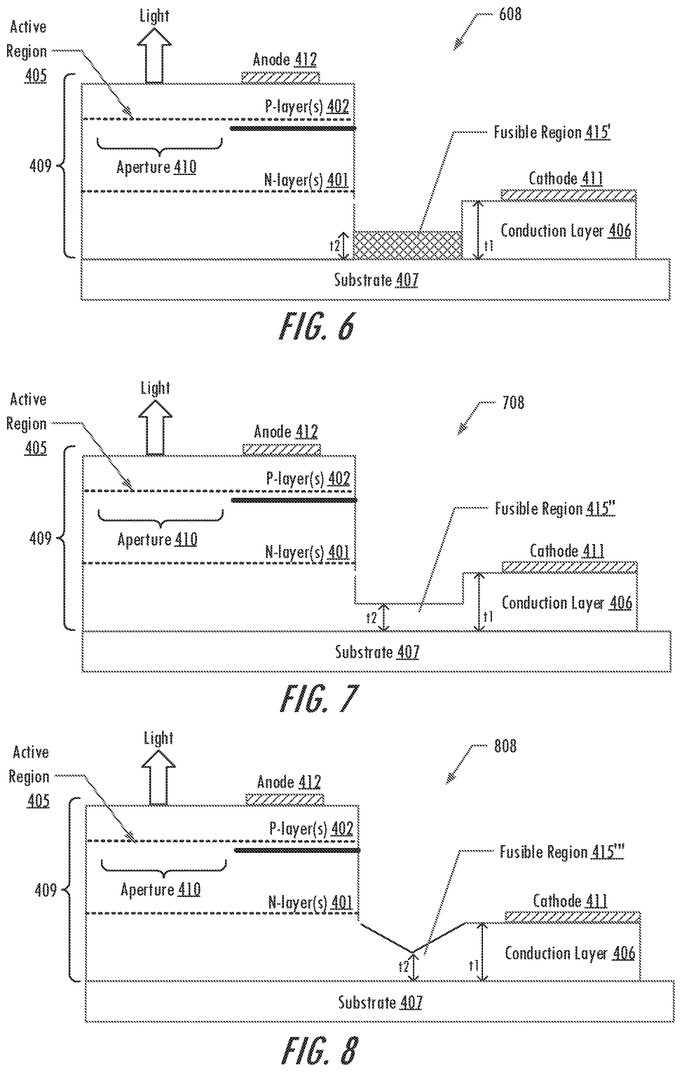

FIGS. 6, 7, and 8 are cross-sectional views illustrating emitters 608, 708, 808 including example integrated fuse structures according to some further embodiments of the present disclosure. As shown in FIGS. 6-8, the integrated fuse structure 415′, 415″, 415′″ may include at least one material and/or dimension that is configured to be transitioned to an electrically-open state responsive to application of a sufficient voltage or associated control signal. For example, the material and/or dimension(s) of the integrated fuse structure 415′, 415″, 415′″ may be configured to provide a higher resistance per unit area than the material and/or dimension(s) of the LCL 406, such that the integrated fuse structure 415′, 415″, 415′″ may be transitioned into the failed or open-circuit state before the remainder of the LCL 406. In some embodiments, the dimensions of the integrated fuse structure 415′, 415″, 415′″ may be between about 0.5 μm (micrometers) to about 3 μm in thickness, about 1 μm to about 300 μm in width, and/or about 1 μm to about 50 μm in length.

In FIG. 6, the integrated fuse structure 415′ may be formed of a different material or may otherwise be configured with different electrical characteristics than the LCL 406. The material of the integrated fuse structure 415′ may have a higher resistance per unit area than the material of the LCL 406, and/or may have a smaller cross-sectional area than the LCL 406, for example, based on at least one dimension (e.g., a thickness t2) that is less than at least one dimension (e.g., a thickness t1) of the LCL 406. In FIG. 7, the integrated fuse structure 415″ may be formed of the same material as or integral to the LCL 406, but may include one at least one dimension (e.g., a thickness t2) that is less than at least one dimension (e.g., a thickness t1) of the LCL 406 (e.g., having a step difference therebetween) to provide the increased resistance. In FIG. 8, the integrated fuse structure 415′″ may likewise be integral to the LCL 406 with at least one dimension (e.g., a thickness t2) that is less than at least one dimension (e.g., a thickness t1) of the LCL 406, but may be formed in a notched shape. Other variations in materials, elements, fabrication, and/or relative dimensions of the integrated fuse structure 415′, 415″, 415′″ may be similarly used to ensure that, responsive to the applied control signal, the integrated fuse structure 415′, 415″, 415′″ transitions to the electrically-open state prior to other serially-connected elements or portions of the emitter 408. For example, one or more selective deposition, doping, and/or etching steps may be used to form the fuse structures 415, 415′, 415″, and/or 415′″ with the desired relative dimensions and/or resistance characteristics.

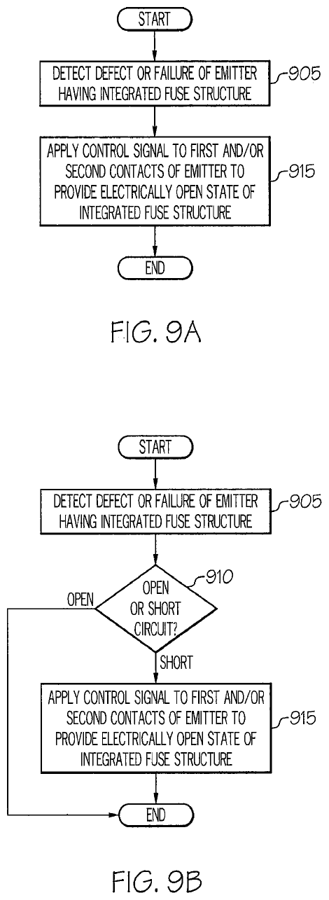

FIGS. 9A and 9B are flowcharts illustrating methods of operating an emitter array to reduce and/or eliminate effects of defective emitters according to some embodiments of the present disclosure. As shown in FIGS. 9A and 9B, a control circuit (such as the control circuit 105) is configured to detect a defect or failure of at least one of the emitters in an emitter array at block 905. One or more of the emitters includes an integrated fuse structure that is electrically coupled between first and second electrical contacts (for example, cathode and anode contacts) thereof. At block 915, the control circuit is configured to selectively apply a control signal to the first and/or second electrical contacts of the one or more emitters. For example, the control circuit may be configured to apply a control signal with sufficient voltage in a forward bias direction to a specific emitter or group of emitters, for example, using probe tips contacting the array interconnect metal on the anode and cathode sides of the device, and/or using selective addressing to isolate the specific emitter(s) that were detected as defective or failed devices at block 905. The integrated fuse structure(s) of the detected emitter(s) is configured to provide an electrically open state between the first and second electrical contacts responsive to the control signal.

In some embodiments, as shown in FIG. 9B, the control circuit may be configured to selectively apply the control signal based on whether the detected failure(s) are due to an open-circuit or a short-circuit. In particular, as shown in FIG. 9B, responsive to detecting the defect or failure at block 905, the control circuit may be configured to determine whether the failure is an open-circuit or a short-circuit condition at block 910. If the defect or failure is determined as an open-circuit at block 910, no further action is taken. If the defect or failure is determined as a short-circuit condition at block 910, the control signal is selectively applied to the defective or failed emitter(s) at block 915, to actuate the corresponding integrated fuse structure(s) to transform the short-circuit condition into an open-circuit condition.

Lidar systems and arrays described herein may be applied to ADAS (Advanced Driver Assistance Systems), autonomous vehicles, UAVs (unmanned aerial vehicles), industrial automation, robotics, biometrics, modeling, augmented and virtual reality, 3D mapping, and security. In some embodiments, the emitter array may include a non-native substrate that is different from a source wafer or substrate on which the emitters were formed (e.g., a curved or flexible substrate) having thousands of discrete emitter elements electrically connected in series (e.g., anode-to-cathode) and/or parallel thereon, with the driver circuit implemented by driver transistors integrated on the non-native substrate adjacent respective rows and/or columns of the emitter array, as described for example in U.S. Patent Application Publication No. 2018/0301872 to Burroughs et al., the disclosure of which is incorporated by reference herein.

Various embodiments have been described herein with reference to the accompanying drawings in which example embodiments are shown. These embodiments may, however, be embodied in different forms and should not be construed as limited to the embodiments set forth herein. Rather, these embodiments are provided so that this disclosure is thorough and complete and fully conveys the inventive concept to those skilled in the art. Various modifications to the example embodiments and the generic principles and features described herein will be readily apparent. In the drawings, the sizes and relative sizes of layers and regions are not shown to scale, and in some instances may be exaggerated for clarity.

The example embodiments are mainly described in terms of particular methods and devices provided in particular implementations. However, the methods and devices may operate effectively in other implementations. Phrases such as “example embodiment”, “one embodiment” and “another embodiment” may refer to the same or different embodiments as well as to multiple embodiments. The embodiments will be described with respect to systems and/or devices having certain components. However, the systems and/or devices may include fewer or additional components than those shown, and variations in the arrangement and type of the components may be made without departing from the scope of the inventive concepts.

The example embodiments will also be described in the context of particular methods having certain steps or operations. However, the methods and devices may operate effectively for other methods having different and/or additional steps/operations and steps/operations in different orders that are not inconsistent with the example embodiments. Thus, the present inventive concepts are not intended to be limited to the embodiments shown, but are to be accorded the widest scope consistent with the principles and features described herein.

It will be understood that when an element is referred to or illustrated as being “on,” “connected,” or “coupled” to another element, it can be directly on, connected, or coupled to the other element, or intervening elements may be present. In contrast, when an element is referred to as being “directly on,” “directly connected,” or “directly coupled” to another element, there are no intervening elements present.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise.

It will also be understood that the term “and/or” as used herein refers to and encompasses any and all possible combinations of one or more of the associated listed items. It will be further understood that the terms “include,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the disclosure are described herein with reference to illustrations that are schematic illustrations of idealized embodiments (and intermediate structures) of the invention. As such, variations from the shapes of the illustrations as a result, for example, of manufacturing techniques and/or tolerances, are to be expected. Thus, the regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defined herein. All publications, patent applications, patents, and other references mentioned herein are incorporated by reference in their entireties.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments of the present invention described herein, and of the manner and process of making and using them, and shall support claims to any such combination or subcombination.

Although the invention has been described herein with reference to various embodiments, it will be appreciated that further variations and modifications may be made within the scope and spirit of the principles of the invention. While specific terms are employed, they are used in a generic and descriptive sense only and not for purposes of limitation, the scope of the present invention being set forth in the following claims.

1. A light emitting device, comprising:
a semiconductor structure comprising an n-type layer, an active region, and a p-type layer;
first and second electrical contacts on the n-type layer and the p-type layer, respectively; and
an integrated fuse structure in or on the semiconductor structure and electrically coupled to the first and/or second electrical contacts,
wherein the integrated fuse structure is actuatable to provide an electrically open state responsive to a control signal.

2. The light emitting device of claim 1, wherein the integrated fuse structure is electrically coupled in series between the first and second electrical contacts and is actuatable to provide the electrically open state between the first and second electrical contacts responsive to application of the control signal to the first and/or second electrical contacts.

3. The light emitting device of claim 2, wherein the control signal comprises a fusing voltage that is greater than an operating voltage of the light emitting device.

4. The light emitting device of claim 3, wherein the fusing voltage is about 2.5 to about 4 times the operating voltage.

5. The light emitting device of claim 1, wherein the integrated fuse structure has a greater resistance than one or more elements that are electrically coupled in series between the first and second electrical contacts.

6. The light emitting device of claim 5, wherein:
the semiconductor structure further comprises a conduction layer that laterally extends beyond the active region and includes one of the first and second electrical contacts thereon; and
the one or more elements comprises a portion of the conduction layer.

7. The light emitting device of claim 6, wherein the integrated fuse structure comprises one or more dimensions that are less than that of the portion of the conduction layer.

8. The light emitting device of claim 7, wherein the one or more dimensions is between about 0.5 μm (micrometer) to about 3 μm in thickness, about 1 μm to about 300 μm in width, and/or about 1 μm to about 50 μm length.

9. The light emitting device of claim 7, wherein the portion of the conduction layer is a first portion, and the integrated fuse structure comprises a second portion of the conduction layer that is integral to the first portion.

10. The light emitting device of claim 1, wherein the light emitting device is a laser diode.

11. The light emitting device of claim 10, wherein the laser diode is a vertical cavity surface emitting laser (VCSEL).

12. An emitter array, comprising:
a plurality of light emitting devices electrically connected in series and/or parallel on a substrate, wherein the light emitting devices respectively comprise:
a semiconductor structure comprising an n-type layer, an active region, and a p-type layer;
first and second electrical contacts on the n-type layer and the p-type layer, respectively; and
an integrated fuse structure in or on the semiconductor structure and electrically coupled to the first and/or second electrical contacts,
wherein the integrated fuse structure is actuatable to provide an electrically open state responsive to a control signal.

13. The emitter array of claim 12, wherein the integrated fuse structure is electrically coupled in series between the first and second electrical contacts and is actuatable to provide the electrically open state between the first and second electrical contacts responsive to application of the control signal to the first and/or second electrical contacts.

14. The emitter array of claim 13, wherein the control signal comprises a fusing voltage that is greater than an operating voltage of the light emitting devices.

15. The emitter array of claim 14, wherein the light emitting devices are individually addressable for selective application of the control signal to one or more of the light emitting devices.

16. The emitter array of claim 12, wherein the integrated fuse structure has a greater resistance than one or more elements that are electrically coupled in series between the first and second electrical contacts.

17. The emitter array of claim 16, wherein:
the semiconductor structure further comprises a conduction layer that laterally extends beyond the active region and includes one of the first and second electrical contacts thereon; and
the one or more elements comprises a portion of the conduction layer.

18. The emitter array of claim 12, wherein the light emitting devices are laser diodes that are electrically connected in series and/or parallel by thin film interconnects on the substrate, and wherein the substrate is non-native to the laser diodes.

19. The emitter array of claim 18, wherein the laser diodes are vertical cavity surface emitting lasers (VCSELs).

20. A method of fabricating a light emitting device, the method comprising:
forming a semiconductor structure comprising an n-type layer, an active region, and a p-type layer;
forming first and second electrical contacts on the n-type layer and the p-type layer, respectively; and
providing an integrated fuse structure in or on the semiconductor structure and electrically coupled to the first and/or second electrical contacts,
wherein the integrated fuse structure is actuatable to provide an electrically open state responsive to a control signal.

21. The method of claim 20, wherein the integrated fuse structure is electrically coupled in series between the first and second electrical contacts and is actuatable to provide the electrically open state between the first and second electrical contacts responsive to application of the control signal to the first and/or second electrical contacts.

22. The method of claim 21, wherein the integrated fuse structure has a greater resistance than one or more elements that are electrically coupled in series between the first and second electrical contacts.

23. The method of claim 22, wherein:
forming the semiconductor structure comprises forming a conduction layer that laterally extends beyond the active region;
forming the first and second electrical contacts comprises forming one of the first and second electrical contacts on the conduction layer; and
the one or more elements comprises a portion of the conduction layer.

24. The method of claim 23, wherein providing the integrated fuse structure comprises forming the integrated fuse structure with at least one dimension that is less than that of the portion of the conduction layer.

25. The method of claim 24, wherein the portion of the conduction layer is a first portion, and the integrated fuse structure comprises a second portion of the conduction layer that is integral to the first portion.

26. A method of operating an emitter array comprising a plurality of light emitting devices electrically connected in series and/or parallel, the method comprising:
performing, by one or more control circuits, operations comprising:
detecting a failure of at least one of the light emitting devices, wherein the at least one of the light emitting devices comprises an integrated fuse structure in or on a semiconductor structure thereof and electrically coupled to first and/or second electrical contacts thereof; and
applying a control signal to the at least one of the light emitting devices, wherein the integrated fuse structure is actuatable to provide an electrically open state responsive to the control signal.

27. The method of claim 26, wherein the integrated fuse structure is electrically coupled in series between the first and second electrical contacts and is actuatable to provide the electrically open state between the first and second electrical contacts responsive to application of the control signal to the first and/or second electrical contacts.

28. The method of claim 27, wherein the control signal comprises a fusing voltage that is greater than an operating voltage of the light emitting devices.

29. The method of claim 28, wherein the fusing voltage is about 2.5 to about 4 times the operating voltage.

30. The method of claim 26, wherein the operations further comprise:
identifying the failure of the at least one of the light emitting devices as an electrical short between the first and second electrical contacts thereof,
wherein applying the control signal comprises selectively applying the control signal to the first and/or second electrical contacts of the at least one of the light emitting devices responsive to the identifying.

31. The method of claim 26, wherein the integrated fuse structure has a greater resistance than one or more elements that are electrically coupled in series between the first and second electrical contacts.

32. The method of claim 31, wherein the light emitting devices are laser diodes that are electrically connected in series and/or parallel by thin film interconnects on a substrate that is non-native to the laser diodes, and are individually addressable by the one or more control circuits for selective application of the control signal thereto.

33. The emitter array of claim 12, wherein the emitter array is a light source of a Light Detection and Ranging (LIDAR) system and/or is configured to be coupled to a vehicle and oriented relative to an intended direction of travel of the vehicle.

34. (canceled)
